(19) United States
(12) Patent Application Publication
(10) Pub. No.: US 2025/0194351 A1
(43) Pub. Date: Jun. 12, 2025

(54) DISPLAY DEVICE

(71) Applicant: Japan Display Inc., Tokyo (JP)

(72) Inventors: Hayata AOKI, Tokyo (JP); Jun NITTA, Tokyo (JP); Marina MOCHIZUKI, Tokyo (JP)

(73) Assignee: Japan Display Inc., Tokyo (JP)

(21) Appl. No.: 18/976,432

(22) Filed: Dec. 11, 2024

(30) Foreign Application Priority Data
Dec. 12, 2023 (JP) 2023-209218

(51) Int. Cl. H10K 59/122

(52) U.S. Cl. CPC H10K 59/122

(57) ABSTRACT

According to one embodiment, in a display device, each of a plurality of pixels includes, on a base, an anode, an organic EL layer provided on the anode, a protective layer provided to cover a side surface of the organic EL layer, and a cathode provided on the protective layer and in an aperture of a bank, so as to be in contact with the organic EL layer, and the protective layer includes a side wall provided on a side surface of the organic EL layer, and a first upper layer provided on an upper surface of the organic EL layer, and a sacrificial layer is provided on an upper surface of the first upper layer so as to be in close proximity to the organic EL layer.

### CROSS-REFERENCE TO RELATED APPLICATION

This application is based upon and claims the benefit of priority from Japanese Patent Application No. 2023-209218, filed Dec. 12, 2023, the entire contents of which are incorporated herein by reference.

### FIELD

Embodiments described herein relate generally to a display device.

### BACKGROUND

Organic electroluminescence (organic EL) display devices that emit light by using the energy released when holes injected from the anode recombine with electrons injected from the cathode have been developed.

### BRIEF DESCRIPTION OF THE DRAWINGS

FIG. 1 is a perspective view showing an entire display device according to an embodiment.

FIG. 2 is a partial plan view schematically showing a configuration example of the display device.

FIG. 3 is a cross-sectional view of the display device shown in FIG. 2, taken along line A1-A2.

FIG. 4 is a cross-sectional view schematically showing a configuration example of a display device of Embodiment 1.

FIG. 5 is a cross-sectional view schematically showing an example of Embodiment 1.

FIG. 6 is a cross-sectional view illustrating a step in a method of manufacturing the display device of Embodiment 1.

FIG. 7 is a cross-sectional view illustrating another step in the method of manufacturing the display device of Embodiment 1.

FIG. 8 is a cross-sectional view illustrating still another step in the method of manufacturing the display device of Embodiment 1.

FIG. 9 is a cross-sectional view illustrating still another step in the method of manufacturing the display device of Embodiment 1.

FIG. 10 is a cross-sectional view illustrating still another step in the method of manufacturing the display device of Embodiment 1.

FIG. 11 is a cross-sectional view illustrating still another step in the method of manufacturing the display device of Embodiment 1.

FIG. 12 is a cross-sectional view illustrating still another step in the method of manufacturing the display device of Embodiment 1.

FIG. 13 is a cross-sectional view illustrating still another step in the method of manufacturing the display device of Embodiment 1.

FIG. 14 is a cross-sectional view illustrating still another step in the method of manufacturing the display device of Embodiment 1.

FIG. 15 is a cross-sectional view illustrating still another step in the method of manufacturing the display device of Embodiment 1.

FIG. 16 is a cross-sectional view illustrating still another step in the method of manufacturing the display device of Embodiment 1.

FIG. 17 is a cross-sectional view illustrating still another step in the method of manufacturing the display device of Embodiment 1.

FIG. 18 is a cross-sectional view illustrating still another step in the method of manufacturing the display device of Embodiment 1.

FIG. 19 is a cross-sectional view illustrating still another step in the method of manufacturing the display device of Embodiment 1.

FIG. 20 is a cross-sectional view illustrating still another step in the method of manufacturing the display device of Embodiment 1.

FIG. 21 is a cross-sectional view illustrating still another step in the method of manufacturing the display device of Comparative Example 1.

FIG. 22 is a cross-sectional view illustrating a step in a method of manufacturing a display device of Comparative Example 1.

FIG. 23 is a cross-sectional view illustrating another step in the method of manufacturing the display device of Comparative Example 1.

FIG. 24 is a cross-sectional view illustrating a step in a method of manufacturing a display device of Comparative Example 2.

FIG. 25 is a cross-sectional view showing a configuration example of a display device according to Embodiment 2.

FIG. 26 is a cross-sectional view illustrating another step in the method of manufacturing the display device of Embodiment 2.

FIG. 27 is a cross-sectional view illustrating still another step in the method of manufacturing the display device of Embodiment 2.

FIG. 28 is a cross-sectional view illustrating still another step in the method of manufacturing the display device of Embodiment 2.

FIG. 29 is a cross-sectional view illustrating still another step in the method of manufacturing the display device of Embodiment 2.

### DETAILED DESCRIPTION

In general, according to one embodiment, a display device comprises
a plurality of pixels including a first pixel and a second pixel; and
a bank provided between each adjacent pair of the plurality of pixels,
each of the plurality of pixels comprising, on a base,
an anode,
an organic EL layer provided on the anode,
a protective layer provided to cover a side surface of the organic EL layer, and
a cathode provided on the protective layer and in an aperture of the bank, so as to be in contact with the organic EL layer, wherein
the protective layer comprises a side wall provided on a side surface of the organic EL layer, and a first upper layer provided on an upper surface of the organic EL layer, and
a sacrificial layer is provided on an upper surface of the first upper layer so as to be in close proximity to the organic EL layer.

An object of this embodiment is to provide a display device with an improved display quality.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### Embodiment 1

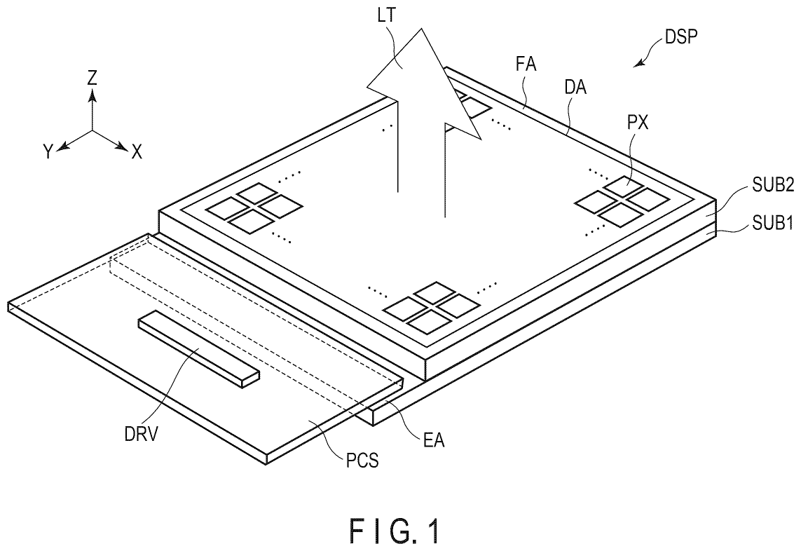

FIG. 1 is a perspective view showing a display device of Embodiment 1 in its entirety. A display device DSP has a display area DA and a peripheral area FA provided to surround the display area DA on a substrate SUB1. The display device DSP includes a plurality of pixels PX arranged in the display area DA. In the display device DSP, light LT is transmitted from a rear surface thereof to a front surface, and vice versa.

The display area DA has an upper surface on which a substrate SUB2 is provided with as a sealing material. The substrate SUB2 is fixed to the substrate SUB1 by sealant (not shown) provided to surround the display area DA. The display area DA formed on the substrate SUB1 is sealed by the substrate SUB2, as the sealing material, and the sealant so as not to be exposed to the atmosphere.

An area EA at an end portion of the substrate SUB1 is located on an outer side the substrate SUB2. In the area EA, a wiring substrate PCS is provided. The wiring substrate PCS is provided with a drive element DRV that outputs video signals and drive signals. The signals from the drive element DRV are input to the pixels PX in the display area DA via the wiring substrate PCS. The pixels PX emit light based on the video signals and various control signals.

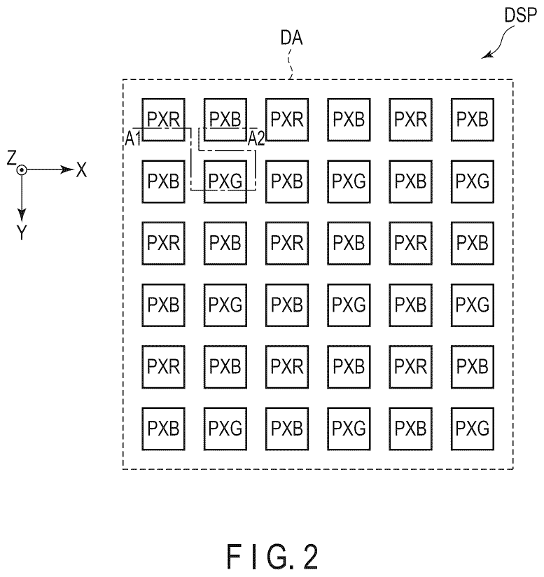

FIG. 2 is a partial plan view schematically showing a configuration example of a display device. The plurality of pixels PX include pixels PXR that emit red light, pixels PXG that emit green light, and pixels PXB that emit blue light. The pixels PXR, pixels PXG, and pixels PXB may as well be referred to as first pixels, second pixels, and third pixels, respectively. Each pixel PXR is arranged adjacent to respective pixels PXB along the first direction X and the second direction Y. Each pixel PXG is arranged adjacent to respective pixels PXB along the first direction X and the second direction Y. Each pixel PXB is arranged adjacent to a respective pixel PXR along the first direction and adjacent to a respective pixel PXG along the second direction Y.

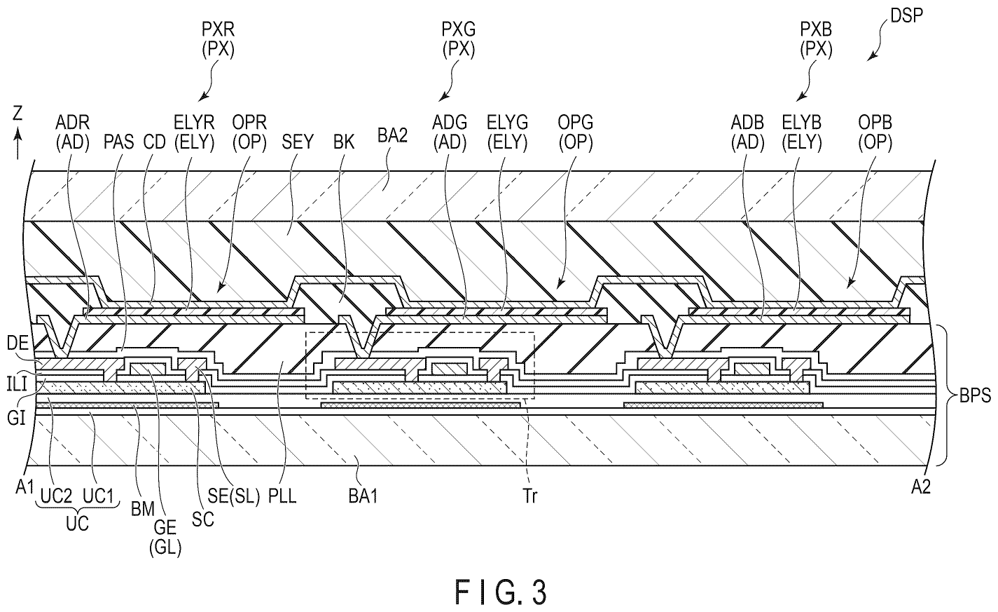

FIG. 3 is a cross-sectional view of the display device shown in FIG. 2 taken along line A1-A2.

A base BAL is made of a material, for example glass or a resin material. As the resin material, for example, acrylic, polyimide, polyethylene terephthalate, polyethylene naphthalate or the like may be used, and it may be formed in a single layer or multiple layers of any of these.

On the base BA1, an insulating layer UC1 is provided. The insulating layer UC1 is formed of a single layer of, for example, silicon oxide film or silicon nitride film or a stacked layer of these.

On the insulating layer UC1, a light shielding layer BM may be provided so as to overlap a transistor Tr. The light shielding layer BM suppresses changes in transistor characteristics due to the entering of light from a rear surface of a channel of the transistor Tr. When the light shielding layer BM is formed from a conductive layer, it is also possible to impart a back gate effect to the transistor Tr by applying a predetermined electric potential.

An insulating layer UC2 is provided to cover the insulating layer UC1 and the light shielding layer BM. For the material of the insulating layer UC2, a material similar to that of the insulating layer UC1 can be used. Note that the insulating layer UC2 may be made of a material different from that of the insulating layer UC1. For example, the insulating layer UC1 may be made of silicon oxide, and the insulating layer UC2 may be made of silicon nitride. The insulating layers UC1 and UC2 are collectively referred to as the insulating layer UC.

On the insulating layer UC, the transistor Tr is provided. The transistor Tr includes a semiconductor layer SC, an insulating layer GI, a gate electrode GE (scanning line), an insulating layer ILI, a source electrode SE (signal line), and a drain electrode DE.

For the semiconductor layer SC, amorphous silicon, polysilicon, or an oxide semiconductor is used.

As the insulating layer GI, a single layer of, for example, silicon oxide or silicon nitride or a stacked layer of these is provided.

For the gate electrode GE, for example, a molybdenum-tungsten alloy (MoW) is used. Note that the gate electrode GE may be formed to be integrated with the respective scanning line GL.

The insulating layer ILI is provided to cover the semiconductor layer SC and the gate electrode GE. The insulating layer ILI is formed from a single layer of, for example, silicon oxide or silicon nitride, or a stacked layer of these.

On the insulating layer ILI, a source electrode SE and a drain electrode DE are provided. The source electrode SE and the drain electrode DE are connected to the source region and the drain region of the semiconductor layer SC, respectively, via contact holes provided in the insulating layer ILI and the insulating layer GI, respectively. The source electrode SE may be formed to be integrated with the respective signal line.

An insulating layer PAS is provided to cover the source electrode SE, the drain electrode DE, and the insulating layer ILI. An insulating layer PLL is provided to cover the insulating layer PAS.

The insulating layer PAS is formed from an inorganic insulating material. The inorganic insulating material may be, for example, a single layer of silicon oxide or silicon nitride or a stacked layer of these. The insulating layer PLL is formed from an organic insulating material. The organic insulating material may be, for example, an organic material such as photosensitive acrylic, polyimide, or the like. With the insulating layer PLL thus provided, steps caused by the transistor Tr can be planarized.

On the insulating layer PLL, an anode AD is provided. The anode AD is connected to the drain electrode DE via respective contact holes provided in the insulating layers PAS and PLL. The anode provided in the pixel PXR is referred to as an anode ADR, the anode provided in the pixel PXB is referred to as an anode ADB, and the anode provided in the pixel PXG is referred to as an anode ADG. When there is no need to distinguish the anode ADR, anode ADG, and anode ADB from each other, they are simply referred to as an anode AD.

The anode AD can be formed, for example, from a stacked body of a reflective electrode and a transparent electrode. The reflective electrode is formed using, for example, a conductive material having a high reflectivity, such as silver (Ag) or aluminum (Al). Apart from this, the reflective electrode RD may as well be formed using an aluminum (Al) alloy. In this case, the reflective electrode RD has a three-layer structure consisting in which a sufficiently thin layer of a barrier metal such as titanium (Ti) is stacked on aluminum (Al) or an aluminum alloy, and further a layer of indium tin oxide (ITO) is stacked on top. Examples of the material that can be alloyed with aluminum include neodymium (Nd), titanium (Ti), tantalum (Ta), and lanthanum (La). The transparent electrode TD is formed using, for example, indium zinc oxide (IZO) or indium zinc oxide (IZO).

In Embodiment 1, the configuration from the base BAL to the insulating layer PLL is referred to as a backplane BPS.

Between each adjacent pair of anodes AD, a bank (which may as well be referred to as a protrusion or a rib) is provided. For the material for the bank BK, an organic material similar to that of the insulating layer PLL is used. The bank BK is opened to expose a part of the anode AD.

An aperture in each pixel PXR is referred to as an aperture OPR, an aperture in each pixel PXB is referred to as an aperture OPB, and an aperture in each pixel PXG is referred to as an aperture OPG. When there is no need to distinguish the aperture OPR, aperture OPB, and aperture OPG, they are simply referred to as apertures OP.

An end portion of the aperture OP should preferably be formed into a smooth tapered shape in a cross-sectional view. If the end portion of the aperture OP is formed into a steep shape, a coverage error may occur in the organic EL layer ELY, which is formed later.

The organic EL layer ELY is provided between each adjacent pair of banks BK so as to overlap the respective anode AD. Although the details thereof will be described more later, the organic EL layer ELY includes an electron transport layer ETY, an emission layer EML, a hole transport layer HTL, and a hole injection layer HIL. The organic EL layer ELY may as well further include an electron injection layer, an electron blocking layer, and a hole blocking layer, if necessary.

The organic EL layer provided in the pixel PXR is referred to as an organic EL layer ELYR, the organic EL layer provided in the pixel PXB is referred to as an organic EL layer ELYB, and the organic EL layer provided in the pixel PXG is referred to as an organic EL layer ELYG. When there is no need to distinguish the organic EL layer ELYR, the organic EL layer ELYG, and the organic EL layer ELYB from each other, they are simply referred to as organic EL layers ELY.

On the organic EL layer ELY, a cathode CD is provided. The cathode CD is formed from, for example, a magnesium-silver alloy (MgAg) film, a single layer of silver (Ag) film, or a stacked layer of silver (Ag) and a transparent conductive material, or the like. For the transparent conductive material, for example, indium tin oxide (ITO), indium zinc oxide (IZO) or the like may be used.

An insulating layer SEY is provided to cover the cathode CD. The insulating layer SEY has a function of preventing moisture from penetrating into the organic EL layer ELY from outside. As the insulating layer SEY, a type having a high gas-barrier property is suitable. As the insulating layer SEY, for example, an insulating layer comprising an organic insulating layer interposed between two inorganic insulating layers containing nitrogen can be used. As the material for the organic insulating layer, acrylic resin, epoxy resin, polyimide resin or the like can be used. As the material for the inorganic insulating layer containing nitrogen, for example, silicon nitride or aluminum nitride can be used.

On the insulating layer SEY, a base BA2 is provided. The base BA2 is formed of a material similar to that of the base BA1. Between the base BA2 and the insulating layer SEY, an inorganic insulating layer or an organic insulating layer having light transmissivity may as well be provided. The organic insulating layer may as well have a function of adhering the insulating layer SEY and the base BA2 with each other.

The light emission generated by the organic EL layer ELY is extracted upwards via the cathode CD. In other words, the display device DSP of this embodiment has a top emission structure.

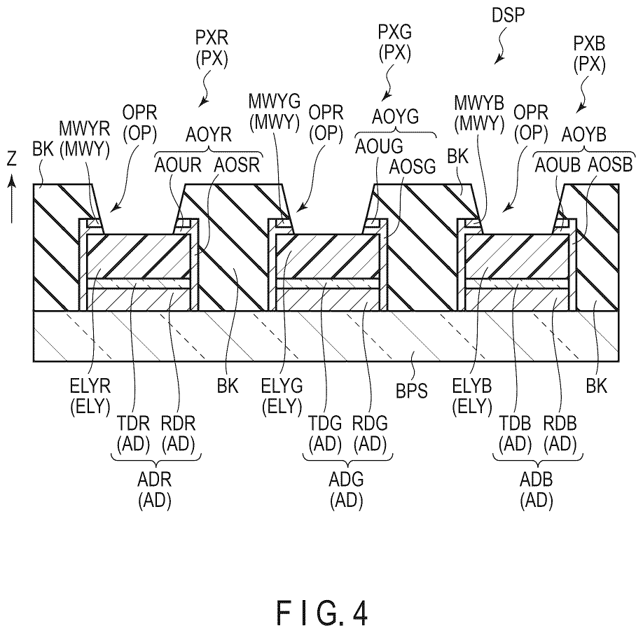

FIG. 4 is a cross-sectional diagram schematically showing an example of the configuration of Embodiment 1. Note that FIG. 4 only shows the configuration in the vicinity of the organic EL layer ELY in the display device DSP. In FIG. 4, the anodes AD (the anode ADR, anode ADG, anode ADB) are provided on the backplane BPS.

On the anode AD, an organic EL layer ELY is provided. On the anode ADR, an organic EL layer ELYR is provided. On the anode ADB, an organic EL layer ELYB is provided. On the anode ADG, an organic EL layer ELYG is provided.

A side wall AOSR is provided to cover side surfaces of the anode ADR and the organic EL layer ELYR. A side wall AOSG is provided to cover side surfaces of the anode ADG and the organic EL layer ELYG. A side wall AOLB is provided to cover side surfaces of the anode ADB and the organic EL layer ELYB.

In the pixel PXR, an upper layer AOUR is provided to overlap a part of the organic EL layer ELYR. In the pixel PXG, an upper layer AOUG is provided to overlap a part of the organic EL layer ELYG. In the pixel PXB, an upper layer AOUB is provided to overlap a part of the organic EL layer ELYB.

The side wall AOSR and the upper layer AOUR are collectively referred to as a protective layer AOYR. The side wall AOSG and the upper layer AOUG are collectively referred to as a protective layer AOYG. The side wall AOSB and the upper layer AOUB are collectively referred to as a protective layer AOYB. When there is no need to distinguish the protective layer AOYR, protective layer AOYG, and protective layer AOYB from each other, they are referred to as protective layers AOL. Note that the protective layers AOL are formed, for example, of aluminum oxide (Alox).

On the protective layer AOL, a sacrificial layer is provided. On the upper layer AOUR, a sacrificial layer MWYR is disposed. On the upper layer AOUG, a sacrificial layer MWYG is disposed. On the upper layer AOUB, a sacrificial layer MWYR is disposed. When there is no need to distinguish the sacrificial layer MWYR, sacrificial layer MWYG, and sacrificial layer MWYB from each other, they are referred to as sacrificial layers MWY.

On the protective layer AOYR and the sacrificial layer MWYR, the protective layer AOYG and the sacrificial layer MWYG, and the protective layer AOYB and the sacrificial layer MWYB, and between each adjacent pair of organic EL layers ELY, a bank BK is provided. The aperture OP (aperture OPR, OPB or OPG) is provided between each adjacent pair of banks BK. Although not shown in FIG. 4, the cathode CD is provided to cover the banks BK, the organic EL layers ELY, the protective layers AOL and the sacrificial layers MWY.

FIG. 5 is a cross-sectional view schematically showing an example of the configuration of Embodiment 1. FIG. 5 is a partial enlarged view of FIG. 4. As shown in FIG. 5, an organic EL layer ELY is provided between the anode AD and the cathode CD along the third direction Z. The organic EL layer ELY includes a hole injection layer HIL, a hole transport layer HTL, an emission layer EML, an electron transport layer ETL, and an electron injection layer EIL, which are stacked one on another along the third direction Z.

In the display device DSP of Embodiment 1, the anode AD, the organic EL layer ELY, and the cathode CD are stacked in this order along the third direction Z. In the organic EL layer ELY, the hole injection layer HIL, the hole transport layer HTL, the emission layer EML, the electron transport layer ETL, and the electron injection layer EIL are stacked in this order along the third direction Z. Note that the configuration of Embodiment 1 is not limited to this. In the display device DSP of Embodiment 1, the layers may be stacked in the order of a cathode CD, a metal oxide layer, an intermediate layer, an organic EL layer ELY, and an anode AD. Further, in the organic EL layer ELY, the layers may be stacked in the order of an electron transport layer ETL, an emission layer EML, a hole transport layer HTL, and a hole injection layer HIL.

The intermediate layer is formed of an amine derivative, for example, polyethyleneimine (PEI). By forming an intermediate layer of an amine derivative, the injection of electrons is increased. In other words, it can as well be said that the intermediate layer is an electron injection layer.

The metal oxide layer is a conductive layer that is transparent, made of, for example, zinc oxide (ZnO).

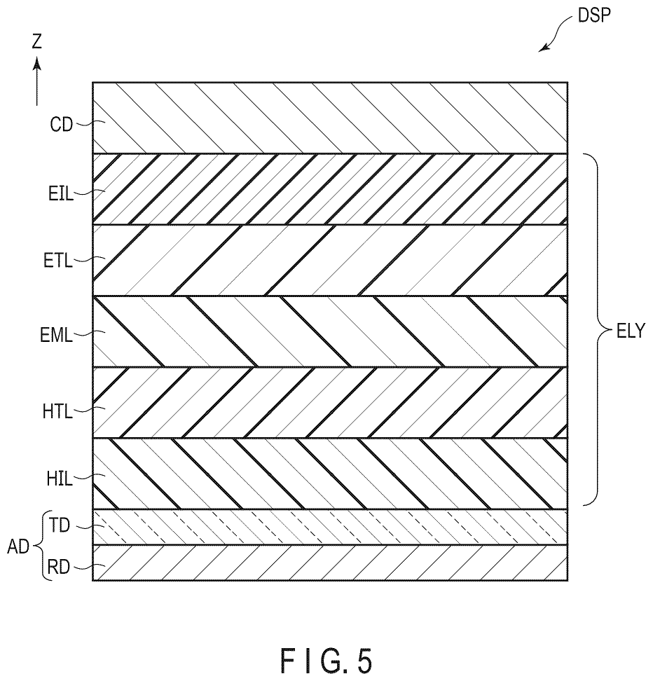

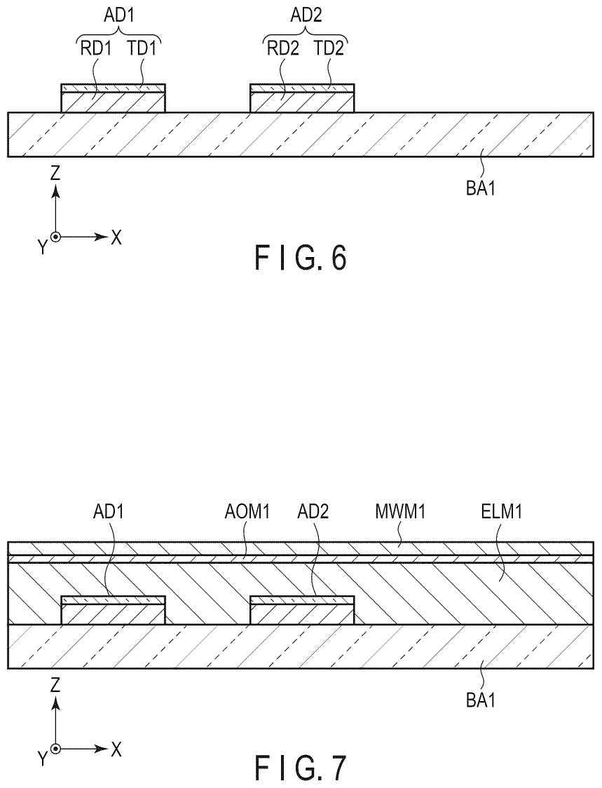

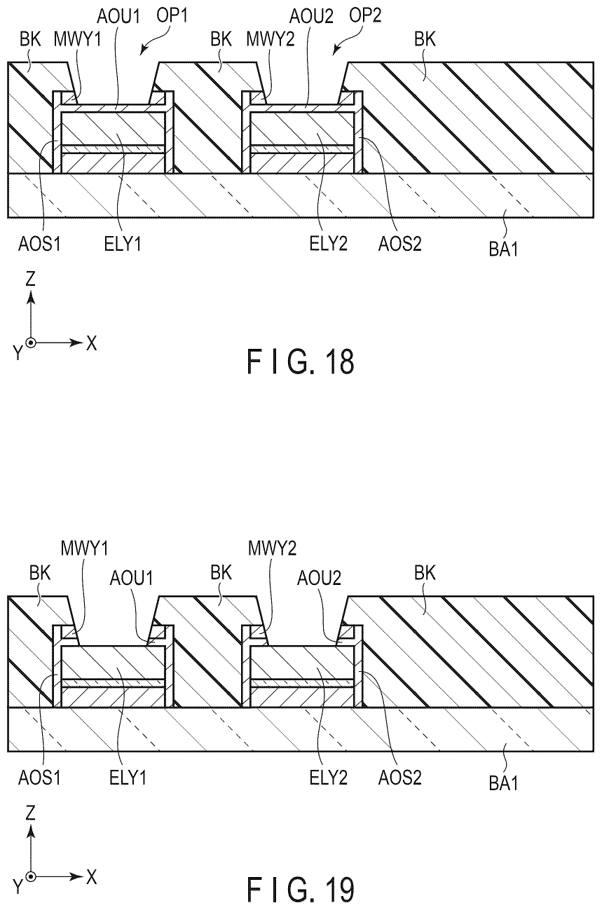

FIGS. 6 to 20 are each a cross-sectional view showing a respective step in a method of manufacturing the display device of Embodiment 1. In FIGS. 6 to 20, the first pixel, which is one of the pixel PXR, pixel PXG, and pixel PXB, is represented as a pixel PX1, and the second pixel, which is another one, is represented as a pixel PX2. In FIGS. 6 to 20, the first pixel (pixel PX1) and the second pixel (pixel PX2) are formed in this order. Although not shown in the figures, the third pixel (which is referred to as a pixel PX3), which is the other one of the pixel PXR, pixel PXG, and pixel PXB, is formed in a manner similar to those of the first and second pixels.

First, the anode AD1 and the anode AD2 are formed on the base BAL (see FIG. 6). The anode AD1 is the anode of the pixel PX1, and the anode AD2 is the anode of the pixel PX2. The anode AD1 includes a reflective electrode RD1 and a transparent electrode TD1. The anode AD2 includes a reflective electrode RD2 and a transparent electrode TD2. Note that the reflective electrode RD1 and the reflective electrode RD2 may have thicknesses less than those of the transparent electrode TD1 and the transparent electrode TD2, respectively.

The organic EL layer ELM1, the sacrificial layer AOM1, and the sacrificial layer MWM1 are formed to cover the base BA1, the anode AD1 and anode AD2, the above-mentioned intermediate layer and the metal oxide layer (see FIG. 7). The organic EL layer ELM1 is an organic EL layer corresponding to the pixel PX1.

The sacrificial layer AOM1 is formed, for example, of aluminum oxide (AlOx). Aluminum oxide can be formed by atomic layer deposition (ALD).

The sacrificial layer MWM1 is formed, for example, of molybdenum tungsten (MoW). The molybdenum tungsten is formed by the sputtering method. The sacrificial layer MWM1 may as well be formed from multiple layers having different etching rates, or may have the etching rate which varies from an upper portion to a lower portion. This is also the case for the sacrificial layer MYY2.

For the sacrificial layer AOM1 and the sacrificial layer MWM1, it is necessary to use materials having different etching rates in the anisotropic etching process, which will be described later. Although the details thereof will be provided later, the upper layer AOU1, the upper layer AOU2, the side wall AOS1, and the side wall AOS2 are formed from a material similar to that of the sacrificial layer AOM1. The sacrificial layer MWY1 and the sacrificial layers MWY2 are formed from a material similar to that of the sacrificial layer MWM1. The etching rates differ from each other among the upper layer AOU1, upper layer AOU2, side wall AOS1, and side wall AOS2, as well as between the sacrificial layer MWY1 and the sacrificial layers MWY2.

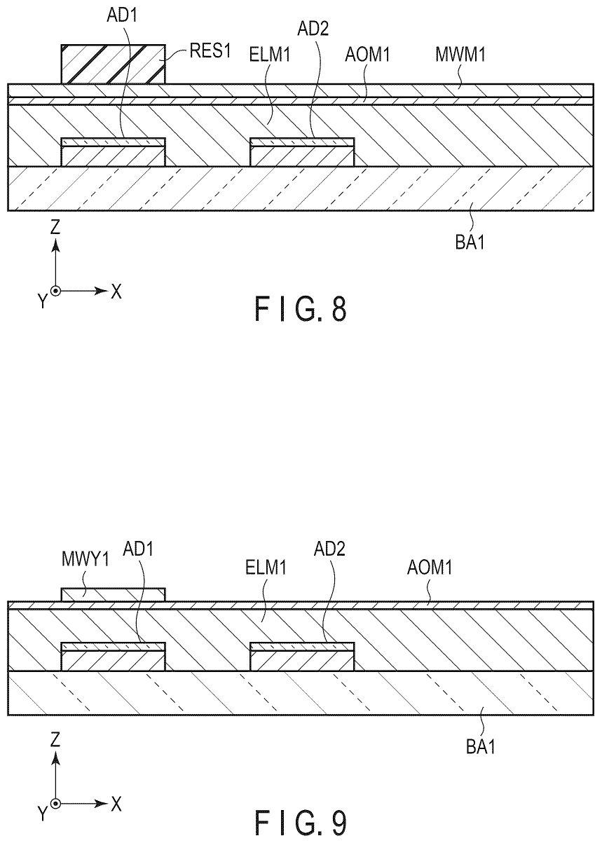

A resist mask RES1 is formed on the sacrificial layer MWM1 so as to oppose the anode AD1 (see FIG. 8). Note that no resist mask is formed on the anode AD2.

Using the resist mask RES1, the sacrificial layer MWM1 is partially removed by etching. With this processing, a sacrificial layer MWY1 is formed into an island-like shape so as to oppose the anode AD1 and interpose the sacrificial layer AOM1 therebetween (see FIG. 9).

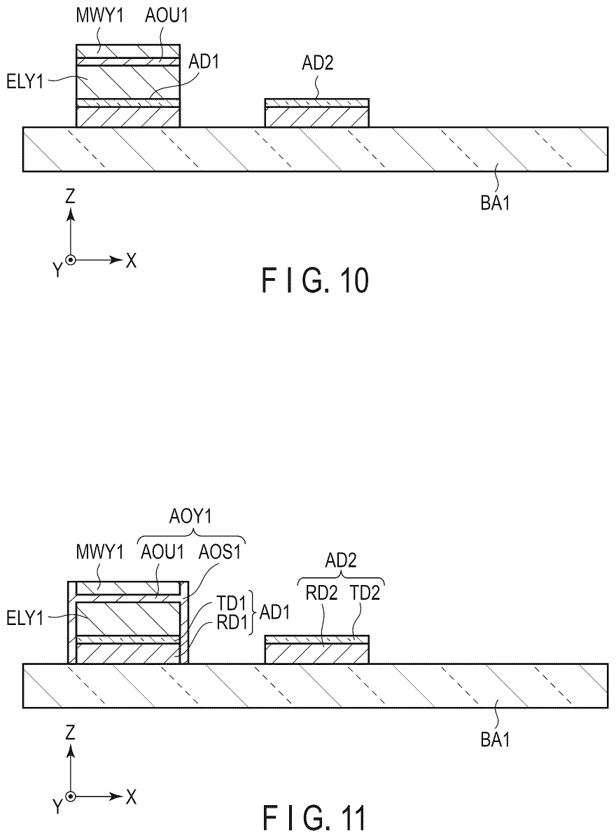

Using the island-shaped sacrificial layer MWY1 as a mask, the sacrificial layer AOM1 and the organic EL layer ELM1 are partially removed by etching. With this processing, the organic EL layer ELY1 and the upper layer of the sacrificial layer AOU1 are formed into an island-like shape between the anode AD1 and the sacrificial layer MWY1 (see FIG. 10). The sacrificial layer AOM1 and the organic EL layer ELM1 on the anode AD2 are removed.

A side wall AOS1 is formed in contact with side surfaces of the anode AD1, the organic EL layer ELY1, the upper layer AOU1, and the sacrificial layer MWY1. The side wall AOS1 is formed from the same material as that of the sacrificial layer AOM1. The upper layer AOU1 and the side wall AOS1 are collectively referred to as the sacrificial layer AOY1 (see FIG. 11).

In order to form the side wall AOS1, first, a material film that give rise to the side wall AOS1 is formed to as to covering the stacked body of the organic EL layer ELY1, the upper layer AOU1, and the sacrificial layer MWY1. After that, the material film is subjected to anisotropic etching, and thus only the area that is in contact with the side surface of the stacked body is left and the other areas are removed.

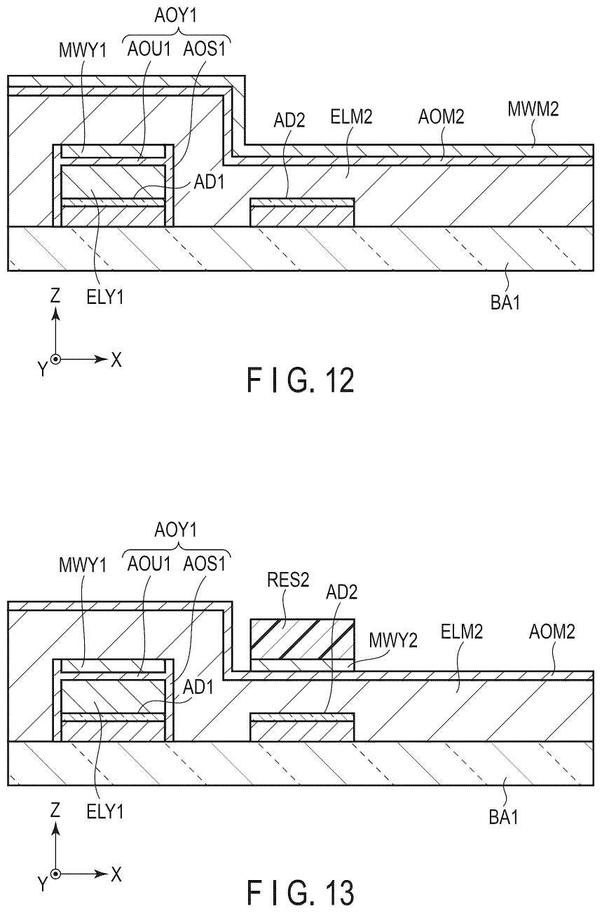

An organic EL layer ELM2, a sacrificial layer AOM2, and a sacrificial layer MWM2 are formed so as to cover the base BA1, the sacrificial layer AOY1, the sacrificial layer MWM1, and the anode AD2 (see FIG. 12). The organic EL layer ELM2 is an organic EL layer corresponding to the pixel PX2.

A resist mask RES2 is formed on the sacrificial layer MWM2 so as to oppose the anode AD2. Using the resist mask RES2, the sacrificial layer MWM2 is partially removed by etching. With this processing, a sacrificial layer MWY2 is formed into an island-like shape so as to oppose the anode AD2 and interpose the sacrificial layer AOM2 therebetween (see FIG. 13).

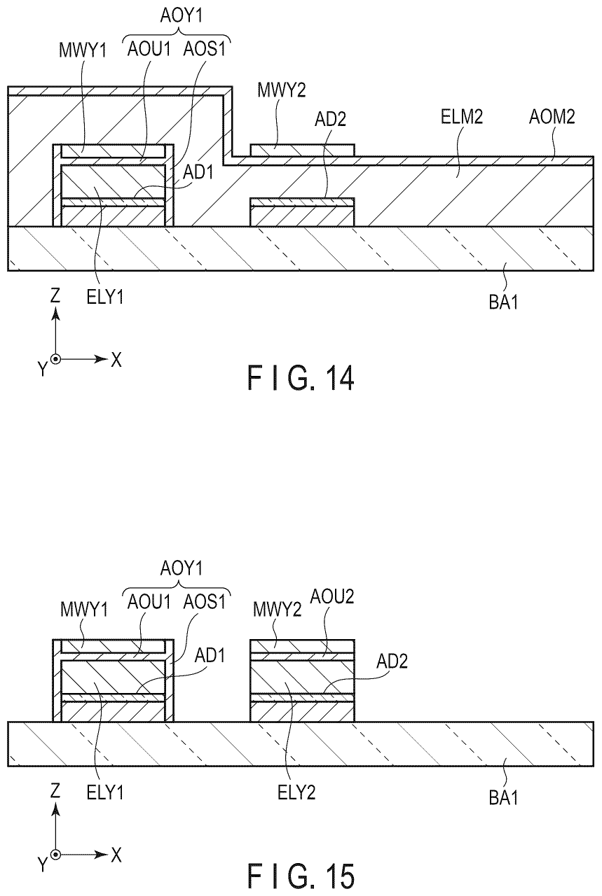

Next, the resist mask RES2 on the sacrificial layer MWY2 is removed (see FIG. 14).

Using the island-shaped sacrificial layer MWY2 as a mask, the sacrificial layer AOM2 and the organic EL layer ELM2 are partially removed by etching. With this processing, the organic EL layer ELY2 and the upper layer AOU2 of the sacrificial layer are formed into an island shape between the anode AD2 and the sacrificial layer MWY2 (see FIG. 15).

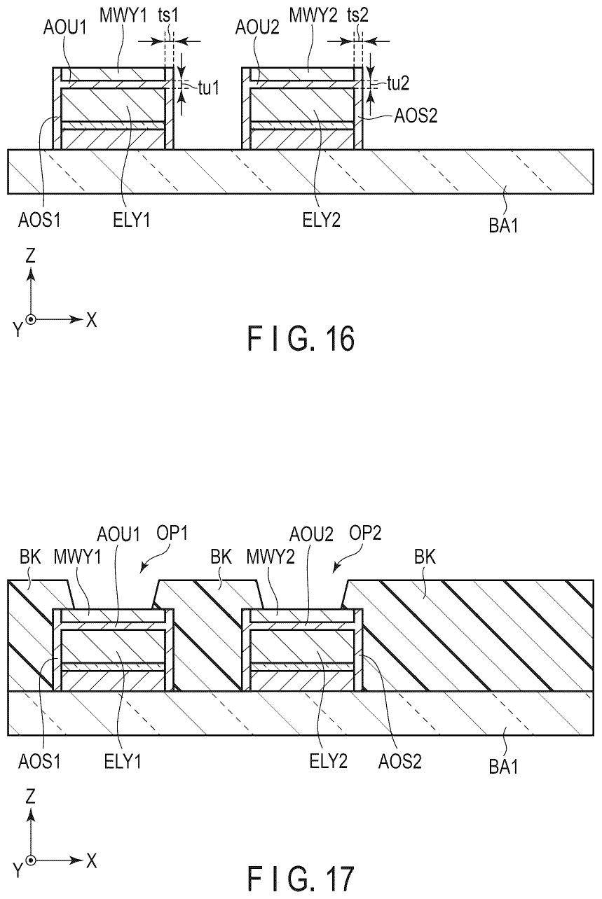

A side wall AOS2 is formed in contact with side surfaces of the anode AD2, the organic EL layer ELY2, the upper layer AOU2, and the sacrificial layer MWY2. The side wall AOS2 is formed of the same material as that of the sacrificial layer AOM2. The upper layer AOU2 and the side wall AOS2 are collectively referred to as the sacrificial layer AOY2 (see FIG. 16).

Here, the thickness of the upper layer AOU1 is defined as tu1, the thickness of the upper layer AOU2 is defined as tu2, the thickness of the side wall AOS1 is defined as ts1, and the thickness of the side wall AOS2 is defined as ts2. Note that the thickness tu1, thickness tu2, thickness ts1, and thickness ts2 are approximately equal to each other.

The bank BK is formed between the organic EL layer ELY1 and the organic EL layer ELY2, so as to be in contact with the side wall AOS1, the side wall AOS2, the sacrificial layer MWY1, and the sacrificial layer MWY2. Note that no bank BK is formed above each of the organic EL layer ELY1 and the organic EL layer ELY2. That is, the aperture OP1 and the aperture OP2 are provided above the organic EL layer ELY1 and the organic EL layer ELY2, respectively (see FIG. 17).

The sacrificial layer MWY1 and the sacrificial layer MWY2 in the aperture OP1 and the aperture OP2 are removed.

The etching is further carried out, and the upper layer AOU1 and the upper layer AOU2 in the aperture OP1 and the aperture OP2 are exposed. Thus, the organic EL layer ELY1 and the organic EL layer ELY2 are exposed in the aperture OP1 and the aperture OP2 (see FIG. 19).

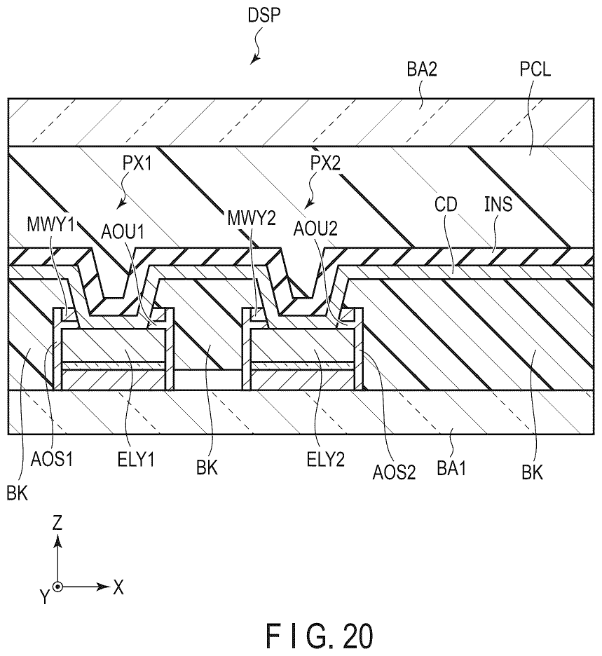

The cathode CD, the insulating layer INS, and the insulating layer PCL are formed to cover the exposed organic EL layer ELY1 and organic EL layer ELY2, and the bank BK. The base BA2 is provided on the insulating layer PCL. (see FIG. 20)

As described above, the display device DSP of Embodiment 1 is formed.

The insulating layer INS is formed, for example, of silicon nitride (SiN). The insulating layer INS prevents moisture from entering the organic EL layer from the outside. The insulating layer PCL is formed, for example, from a resin insulating material. The insulating layer PCL has a function of planarizing the surface. For the base BA2, a material similar to that of the base BAL can be used.

In order to form the anode and the organic EL layer of the pixel PX3, which is the third pixel, the organic EL layer and sacrificial layers should only be formed to cover the anode of the pixel PX3 as in the case of FIG. 12 after the process shown in FIG. 16 is completed. As in the case of the process of FIG. 16, after the side wall of the sacrificial layer of the pixel PX3 is formed, the process can proceed to that shown in FIG. 17.

In this embodiment, the pixel PX1, the pixel PX2, and the pixel PX3 can be a pixel PXR, a pixel PXG, and a pixel PXB, respectively.

As the side wall AOS1 and the side wall AOS2, formed of aluminum oxide covers the side surface of the organic EL layer, it is possible to protect the organic EL layer.

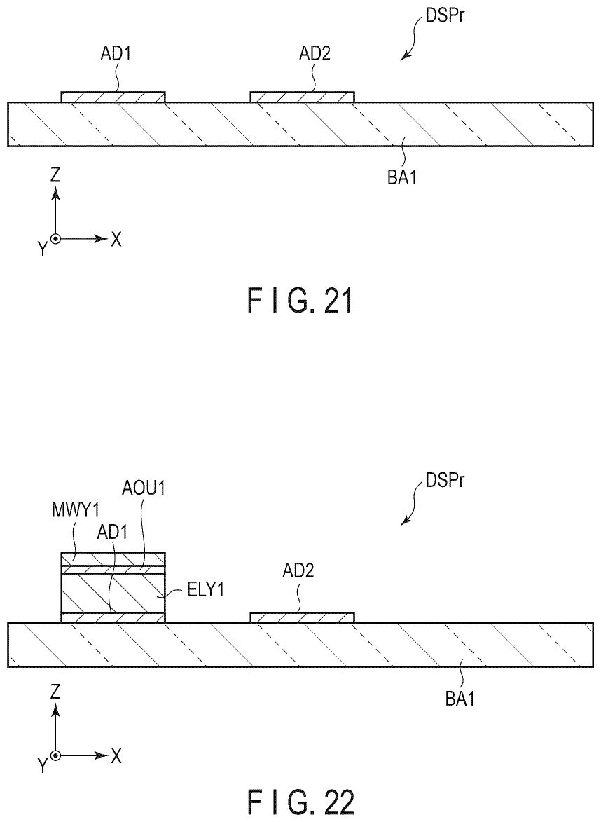

FIGS. 21 to 23 are each a cross-sectional diagram showing a respective step in a method of manufacturing a display device of Comparative Example 1. In the manufacture of a display device DSPr of Comparative Example 1, first, an anode AD1 and an anode AD2 are formed on the base BAL (see FIG. 21). It is assumed here that the anode AD1 and the anode AD2 in the comparative example are transparent electrodes formed of a metal oxide. Example of such a metal oxide include indium tin oxide and indium zinc oxide mentioned above. The process shown in FIG. 21 corresponds to the process shown in FIG. 6.

Through the processing steps shown in FIGS. 7 to 9, the organic EL layer ELY1, the upper layer of the sacrificial layer AOU1, and the sacrificial layer MWY1 are formed on the anode AD1. On the anode AD2, the sacrificial layer has been removed (see FIG. 22). The process shown in FIG. 22 corresponds to the process shown in FIG. 10.

Next, as in FIG. 11, a side wall AOS1 is formed so as to be in contact with side surfaces of the anode AD1, the organic EL layer ELY1, the upper layer AOU1, and the sacrificial layer MWY1. As in the case described above, a material film, which gives rise to the side wall AOS1, is formed to cover the stacked body of the organic EL layer ELY1, the upper layer AOU1, and the sacrificial layer MWY1. Then, the material film is subjected to anisotropic etching so as to leave only the area that is in contact with the side surface of the stacked layer and remove the other areas, thus forming the side wall AOS1.

The material of the side wall AOS1 is the same as that of the sacrificial layer AOM1, that is, for example, aluminum oxide (Alox). On the other hand, the anode AD1 and the anode AD2 are formed of a metal oxide, for example, as described above.

That is, the side wall AOS1, as well as the anode AD1 and the anode AD2, are formed from a material containing a metal oxide. Here, when etching such a metal oxide, it may be necessary in some cases to use an etching gas whose selectivity ratio cannot be taken.

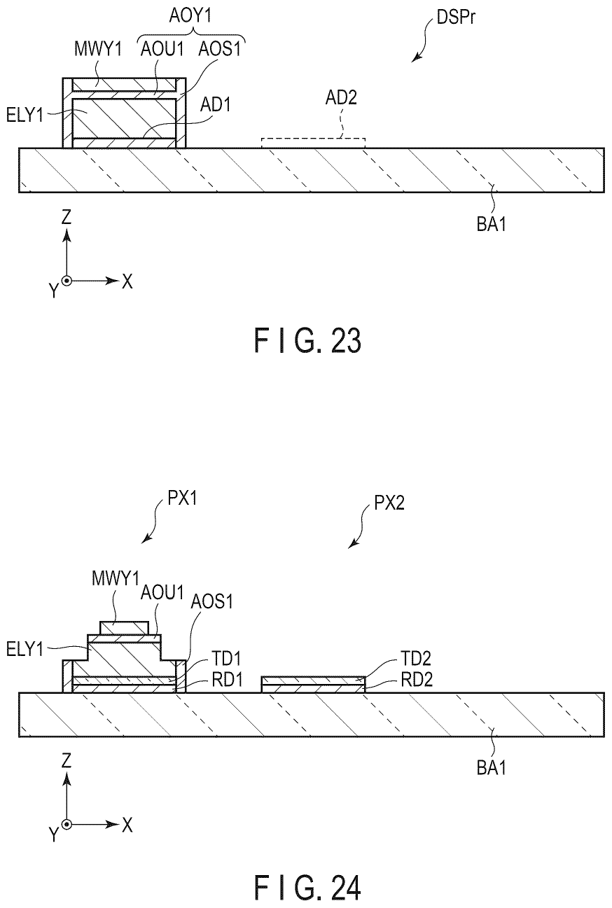

In this case, there is a risk that the anode AD2 may be removed together as well by the etching carried out to form the side wall AOS1 (see FIG. 23). If the anode is removed, the pixel does not properly emit light. In this way, the display quality will be reduced in such a display device.

FIG. 24 is a cross-sectional view showing a processing step in a method of manufacturing a display device of Comparative Example 2. As described above, in the manufacturing process shown in FIG. 11, anisotropic etching is carried out. At this time, if the sacrificial layer MWY1 is thin or narrow in width in plan view, there is a risk that a part of the sacrificial layer MWY1, a part of the side wall AOS1, and a part of the organic EL layer ELY1 of the pixel PX1 as well may be etched. If part of the organic EL layer ELY1 is etched, the light-emitting area of the pixel PX1 is decreased. Further, when the above-described anisotropic etching is carried out in a similar way on the pixel PX2, there is a risk that not only the organic EL layer of the pixel PX2, but also the organic EL layer ELY1 of the pixel PX1 may be etched again.

In Embodiment 1, the sacrificial layer MWY1 and the sacrificial layer MWY2 are provided on the upper layer AOU1 and the upper layer AOU2, respectively. The upper layer AOU1 and the upper layer AOU2, as well as the sacrificial layer MWY1 and the sacrificial layer MWY2 have etching rates different from each other as described above. With this configuration, the upper layer AOU1 and the upper layer AOU2 are not excessively etched, and further the organic EL layer ELY1 is not etched.

As described above, in the display device DSP of Embodiment 1, a part of the sacrificial layer MWY1 and a part of the sacrificial layer MWY2 remain on the upper layer AOU1 and upper layer AOU2, respectively. In addition, the etching rates of the sacrificial layer AOY1 and the sacrificial layer AOY2, as well as the sacrificial layer MWY1 and the sacrificial layer MWY2 are different from each other. With this configuration, the organic EL layer ELY is not etched, and the light-emitting area of the pixel PX is not reduced. Therefore, the display quality of the display device DSP can be improved.

### Embodiment 2

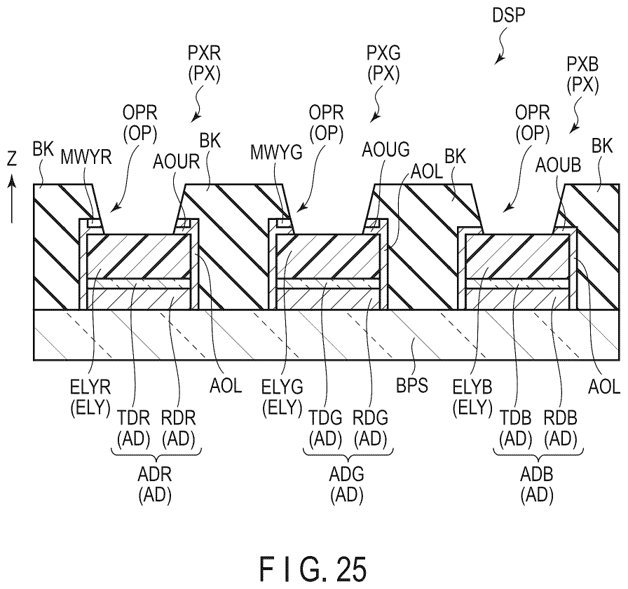

FIG. 25 is a cross-sectional view schematically showing a configuration example of a display device of Embodiment 2. The display device DSP shown in FIG. 25 is different from the display device DSP shown in FIG. 4 in that the sacrificial layer MWYR is not left in the pixel PXB.

In the display device DSP shown in FIG. 25, the sacrificial layer MWYR and the sacrificial layer MWYG are provided on the upper layer AOUR and the upper layer AOUG in the pixel PXR and the pixel PXG, respectively. On the other hand, in the pixel PXB, the sacrificial layer MWYB is not provided on the upper layer AOUB.

In FIG. 25, the pixel PXR and the pixel PXG correspond respectively to the pixel PX1 and the pixel PX2 shown in FIGS. 6 to 19. The pixel PXB corresponds to the pixel PX3 described above.

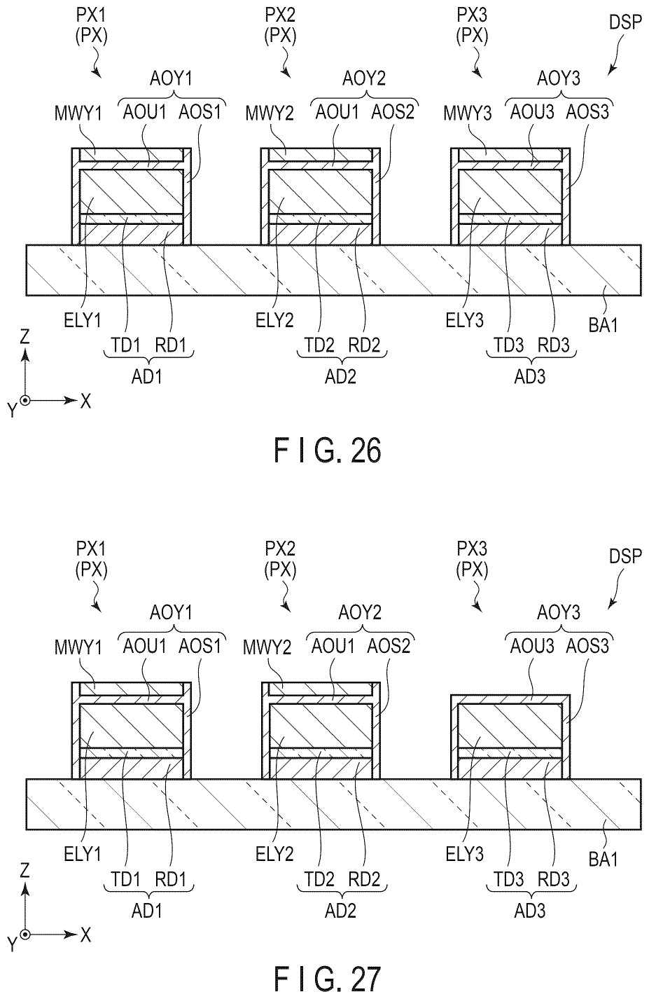

FIGS. 26 to 29 are each a cross-sectional view illustrating a respective processing step in a method of manufacturing a display device of Embodiment 2. In a pixel PX1, pixel PX2, and pixel PX3, a side wall AOS1, side wall AOS2, and side wall AOS3 are formed in a similar manner to that of Embodiment 1 (see FIG. 26). The processing step shown in FIG. 26 corresponds to the step shown in FIG. 16.

In the pixel PX1, an organic EL layer ELY1 is formed on an anode AD1, which includes a reflective electrode RD1 and a transparent electrode TD1. On the organic EL layer ELY1, an upper layer AOU1 of a sacrificial layer AOY1 is formed. On the upper layer AOU1, a sacrificial layer MWY1 is formed. A side wall AOS1 is formed on a side surface of a stacked body of the anode AD1, the organic EL layer ELY1, the upper layer AOU1, and the sacrificial layer MWY1. The upper layer AOU1 and the side wall AOS1 are formed to be integrated as one body into a sacrificial layer AOY1.

In the pixel PX2, an organic EL layer ELY2 is formed on the anode AD2, which includes a reflective electrode RD2 and a transparent electrode TD2. On the organic EL layer ELY2, an upper layer AOU2 of a sacrificial layer AOY2 is formed. On the upper layer AOU2, a sacrificial layer MWY2 is formed. A side wall AOS2 is formed on a side surface of a stacked body of the anode AD2, the organic EL layer ELY2, the upper layer AOU2, and the sacrificial layer MWY2. The upper layer AOU2 and the side wall AOS2 are formed to be integrated as one body into a sacrificial layer AOY2.

In the pixel PX3, an organic EL layer ELY3 is formed on the anode AD3, which includes a reflective electrode RD3 and a transparent electrode TD3. An upper layer AOU3 is formed on the organic EL layer ELY3. A sacrificial layer MYW3 is formed on the upper layer AOU3. A side wall AOS3 is formed on a side surface of a stacked body of the anode AD3, the organic EL layer ELY3, the upper layer AOU3, and the sacrificial layer MWY3. The upper layer AOU3 and the side wall AOS3 are formed to be integrated as one body into a sacrificial layer AOY3.

In the pixel PX3, the entire sacrificial layer MYW3 and the part of the side wall AOS3, which protrudes from the upper layer AOU3 are removed. In other words, the upper layer AOU3 (see FIG. 27) is planarized.

Then, a bank BK is formed so as to be in contact with the side wall AOS1, the sacrificial layer MWY1, the side wall AOS2, the sacrificial layer MWY2, the side wall AOS3, and the upper layer AOU3, and between the organic EL layer ELY1 and the organic EL layer ELY2, and also between the organic EL layer ELY2 and the organic EL layer ELY3.

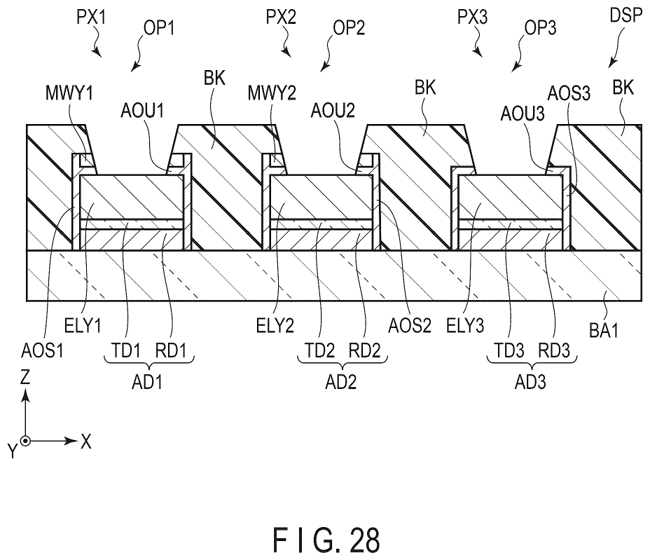

Note that no bank BK is formed above the organic EL layer ELY1, the organic EL layer ELY2, and the organic EL layer ELY3. In other words, an aperture OP1, an aperture OP2, and an aperture OP3 are provided above the organic EL layer ELY1, organic EL layer ELY2, and organic EL layer ELY3, respectively. Within the aperture OP1, aperture OP2, and aperture OP3, the organic EL layer ELY1, organic EL layer ELY2, and organic EL layer ELY3 are exposed respectively (see FIG. 28).

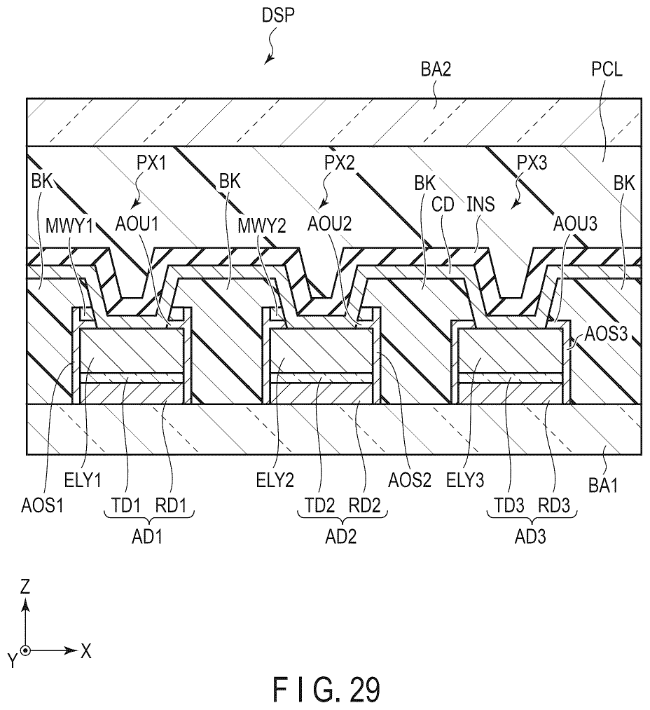

Next, as in the processing step shown in FIG. 20, a cathode CD, am insulating layer INS, and an insulating layer PCL are formed to cover the exposed organic EL layer ELY1, organic EL layer ELY2, and organic EL layer ELY3, as well as the bank BK. A base BA2 is provided on the insulating layer PCL. In this manner, the display device DSP of Embodiment 2 is obtained (see FIG. 29).

In Embodiment 2, another pixel next to the pixel PX3 is not formed, and therefore the side wall AOS3 is not etched any further. With this configuration, it is possible to increase the design margin in the manufacturing process of the display device DSP of Embodiment 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels including a first pixel and a second pixel; and
a bank provided between each adjacent pair of the plurality of pixels,
each of the plurality of pixels comprising, on a base,
an anode,
an organic EL layer provided on the anode,
a protective layer provided to cover a side surface of the organic EL layer, and
a cathode provided on the protective layer and in an aperture of the bank, so as to be in contact with the organic EL layer, wherein
the protective layer comprises a side wall provided on a side surface of the organic EL layer, and a first upper layer provided on an upper surface of the organic EL layer, and
a sacrificial layer is provided on an upper surface of the first upper layer so as to be in close proximity to the organic EL layer.

2. The display device according to claim 1, wherein
the plurality of pixels further include a third pixel, and
the third pixel comprises, on the base,
the anode,
the organic EL layer provided on the anode,
the protective layer provided to cover the side surface of the organic EL layer, and
the cathode provided on the protective layer and in the aperture of the bank, so as to be in contact with the organic EL layer,
the protective layer comprises the side wall provided on the side surface of the organic EL layer and the first upper layer provided on an upper surface of the organic EL layer, and
the sacrificial layer is provided on an upper surface of the first upper layer in close proximity to the side wall.

3. The display device according to claim 1, wherein
the plurality of pixels further include a third pixel, and
the third pixel comprises, on the base,
the anode,
the organic EL layer provided on the anode,
the protective layer provided to cover the side surface of the organic EL layer, and
the cathode provided on the protective layer and in the aperture of the bank, so as to be in contact with the organic EL layer,
the protective layer comprises the side wall provided on the side surface of the organic EL layer and the first upper layer provided on an upper surface of the organic EL layer, and
the third pixel does not include the sacrificial layer.

4. The display device according to claim 1, wherein
the protective layer includes a second upper layer on the sacrificial layer.

5. The display device according to claim 1, wherein
the protective layer is formed of aluminum oxide.

6. The display device according to claim 1, wherein
the sacrificial layer is formed of molybdenum tungsten.
